(19) United States
(12) Patent Application Publication
(10) Pub. No.: US 2009/0065043 A1
(43) Pub. Date: Mar. 12, 2009

(54) METHOD OF COUPLING PHOTOVOLTAIC CELLS AND FILM FOR IMPLEMENTING IT

(76) Inventors: Jean-Christophe Hadorn, Bournens (CH); Olivier Ouzilou, Villeneuve (CH); Sandrine Crisafulli, Geneva (CH); Sylvere Leu, Schonenberg (CH)

Correspondence Address: HOGAN & HARTSON LLP;IP GROUP, COLUMBIA SQUARE, 555 THIRTEENTH STREET, N.W., WASHINGTON, DC, 20004, US

(21) Appl. No.: 12/280,493

(22) PCT Filed: Feb. 22, 2007
(86) PCT No.: PCT/IB07/00428

§ 371 Date: Aug. 22, 2008

(30) Foreign Application Priority Data
Feb. 22, 2006 (IB) PCT/IB2006/000367

(51) Int. Cl. H01L 31/05; H01L 31/18

(52) U.S. Cl. 136/244

(57) ABSTRACT

Method for electrically connecting photovoltaic cells (102) together and for connecting the panels peripherally. The method comprises the use of a flexible film (103) composed of two layers of five materials having different properties. The film (103) has a plurality of through-holes (104) arranged so that they coincide with connection points (107) located on the rear face of the cells (102), so as to allow them to be electrically coupled via the printed macrocircuit (105). The electrical coupling operation is carried out in an automated manner by a lead-free wave soldering method. This method makes it possible for the cost of industrializing solar modules to be considerably reduced, by implementing a continuous method right from the start of the chain up to the lamination step.

This invention relates to the field of photovoltaic cells, in particular a method for electrically coupling cells which is integrated in the solar panel manufacturing process and which enables said manufacturing process to be automated. The method of the invention uses a flexible film to effect the connections between cells and thus allows the production rate of solar panels to be increased, offers much better quality in the soldering carried out and protects the environment. The invention also has as its object solar panels obtained directly by the manufacturing process of the invention and a flexible film permitting the implementation of the method for connecting the cells together. Another object of the invention relates to the use of said flexible film to effect peripheral connections on solar panels made by conventional methods.

Photovoltaic modules raise the low current and low voltage of individual photovoltaic cells by coupling said cells in parallel and in series to obtain a usable service voltage.

The prior art comprises a method of coupling photovoltaic cells in series, or in series and in parallel, that consists of soldering connector strips between the positive poles, generally situated on the rear side of the cell, and the negative poles, generally situated on the front side of said cell, to make the electrical connection between two adjacent cells.

The process of connecting several adjacent cells to obtain a strip generally of 8 to 12 cells using this soldering method is lengthy and complicated.

There exist photovoltaic cells whose positive and negative poles are situated only on the rear side of the cell. For these cells, another method for electrically connecting these photovoltaic cells together, also forming part of the prior art, consists of making the connection either by tabs or by elements called ossicles made of a metal alloy. This method is intricate, often manual, therefore slow and can damage thin cells.

U.S. Pat. No. 4,133,697 discloses a device comprising a printed circuit on which photovoltaic cells are soldered. The device permits some automation of the soldering process. The disadvantage of this method comes mainly from the fact that the solders must be effected on the front and rear sides of the circuit board which makes the operation more complicated. These soldering operations are performed by an infrared lamp which cannot ensure optimum quality of the soldering and presents a risk of damaging the photovoltaic cells.

The aim of this invention is to propose a flexible backing film adapted to a method for coupling photovoltaic cells, said film enabling the automation of the electric coupling of said cells to be simplified. The use of this flexible film permits the cells to be electrically coupled by means of a wave soldering process, which significantly improves productivity, reduces the production time of photovoltaic modules and provides more reliable interconnections.

Another aim of the invention is to make the electrical connection between the cells and the exterior without using lead solder as is the case at present in the photovoltaic industry. Solar panels obtained by the method according to the invention are lead-free which makes them easier to recycle and reduces manufacturing costs.

According to the invention, this aim is achieved by a cell coupling method according to claim 1, together with a flexible film which permits the use of the coupling method according to claim 9. The flexible backing film comprises a macro circuit printed on one side and accommodates the photovoltaic cells on the other side. The backing film comprises a plurality of through-holes positioned so as to coincide with connection points situated on the rear side of said cells, in order to permit automated selective mini-wave soldering to provide the electrical coupling of the photovoltaic cells through the macro printed circuit.

Other characteristics of the invention are stated in the claims and will emerge in the description that follows.

A principal embodiment of the invention will now be described as a non-limitative example, with references to the schematic diagrams appended, in which:

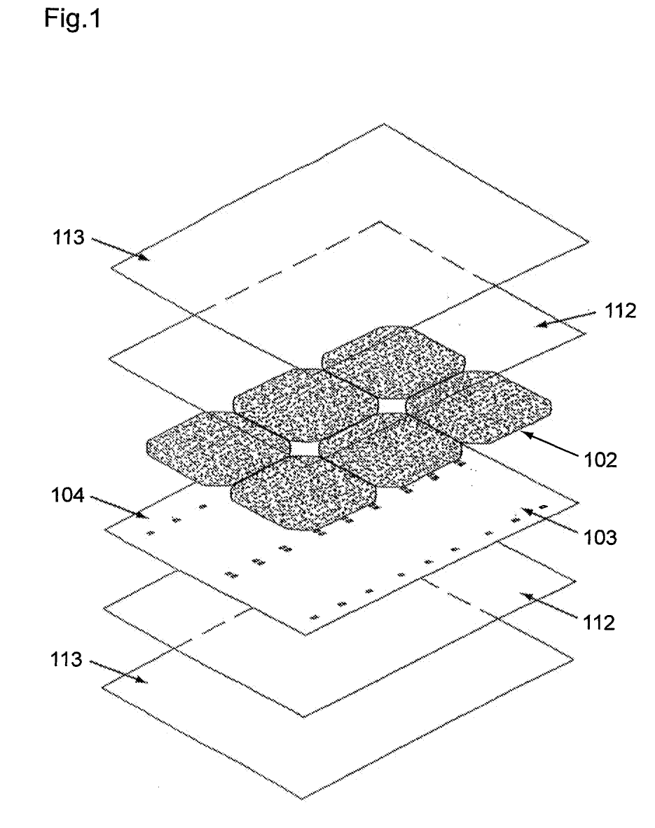

FIG. 1 shows an exploded view in perspective of a photovoltaic module comprised of cells with rear side contacts, the backing film, encapsulating films and protective films.

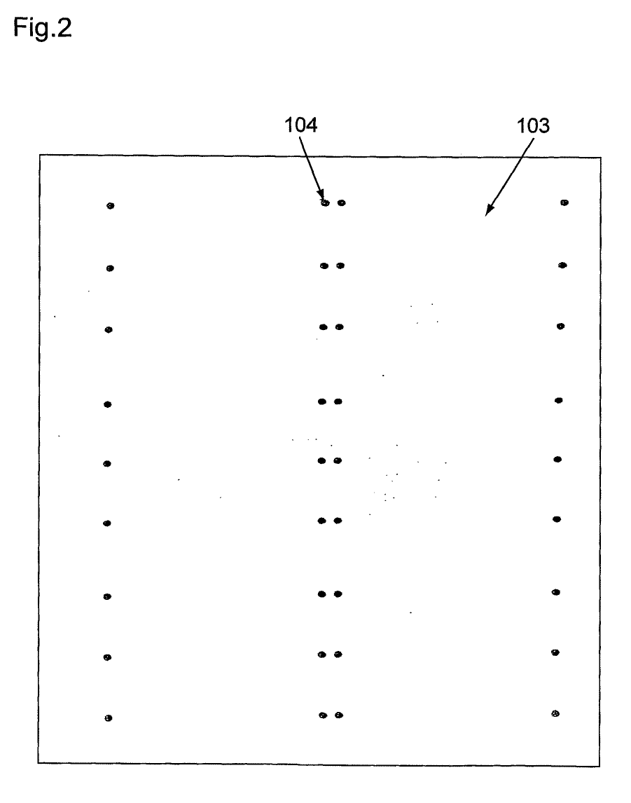

FIG. 2 shows a top view of the backing film with plated holes corresponding to the tacks made by soldering.

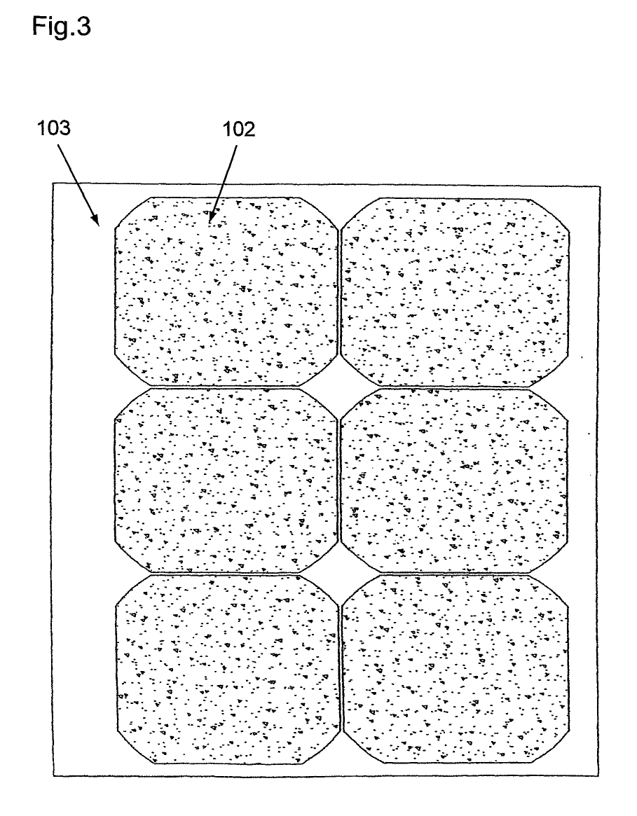

FIG. 3 shows a top view of the backing film to which the photovoltaic cells are fitted.

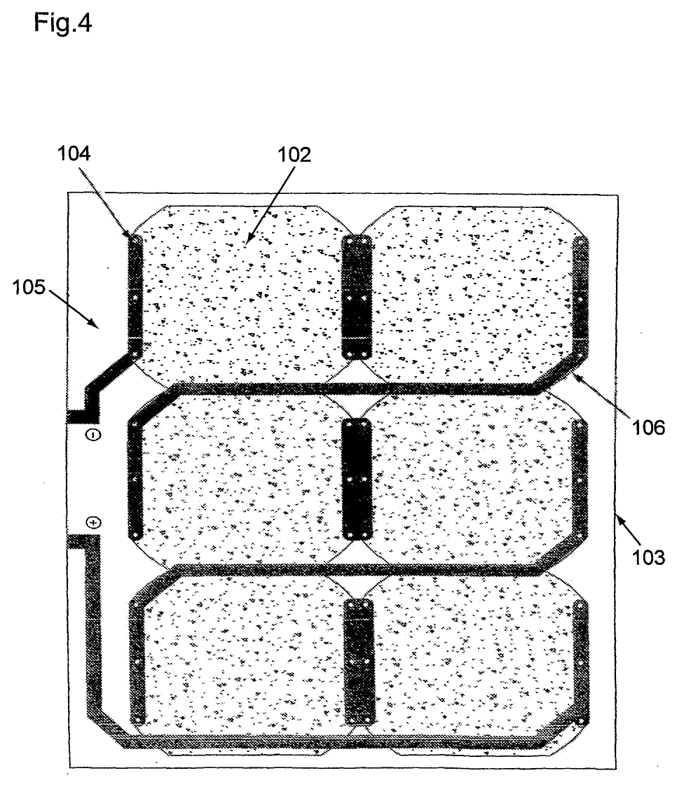

FIG. 4 shows a bottom view of the backing film comprising the macro printed circuit, said film being shown as transparent to allow the photovoltaic cells to be seen.

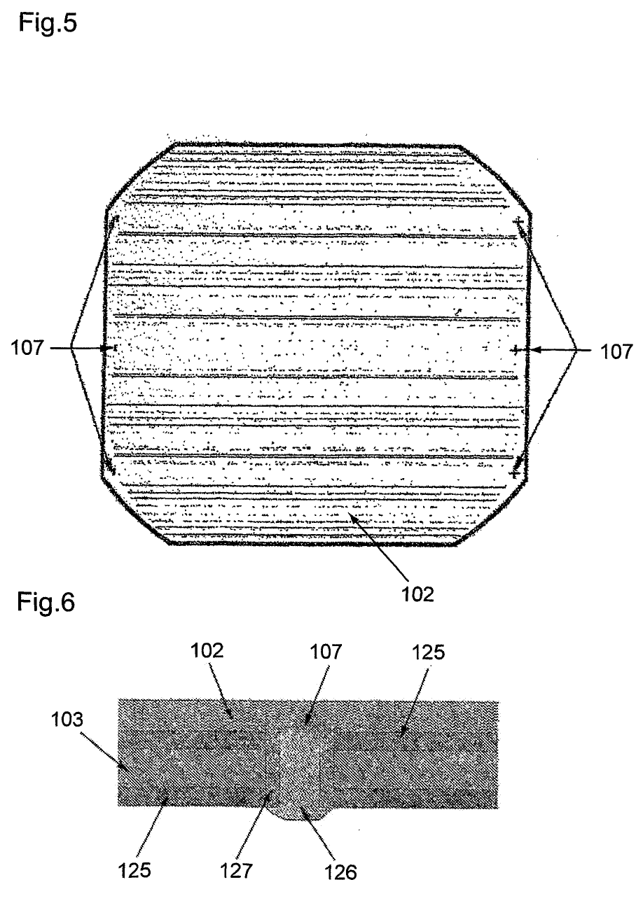

FIG. 5 shows a bottom view of a photovoltaic cell with the connection points.

FIG. 6 shows a partial sectional view of a solder joint.

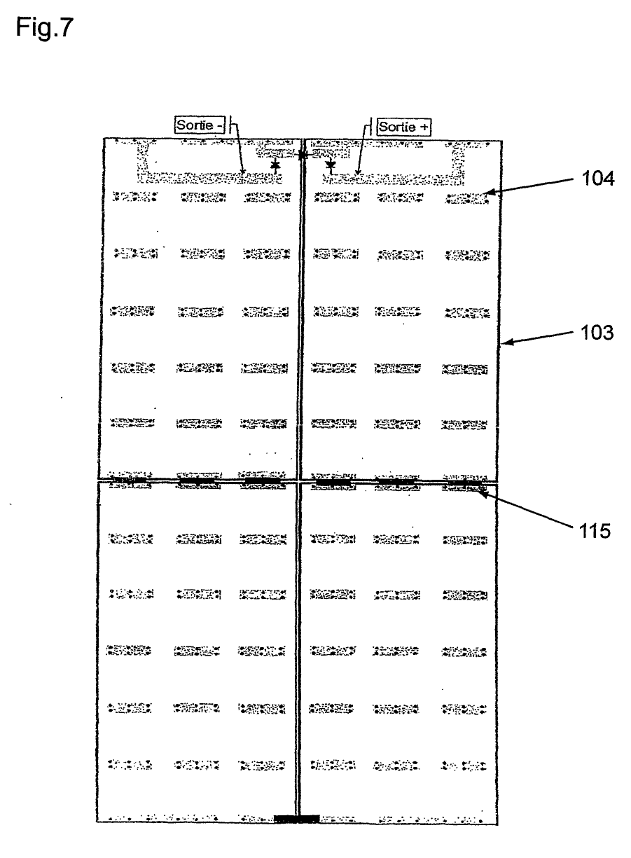

FIG. 7 shows a view, on the side opposite the cells, of four backing films assembled together and designed to receive 72 photovoltaic cells to make up a module.

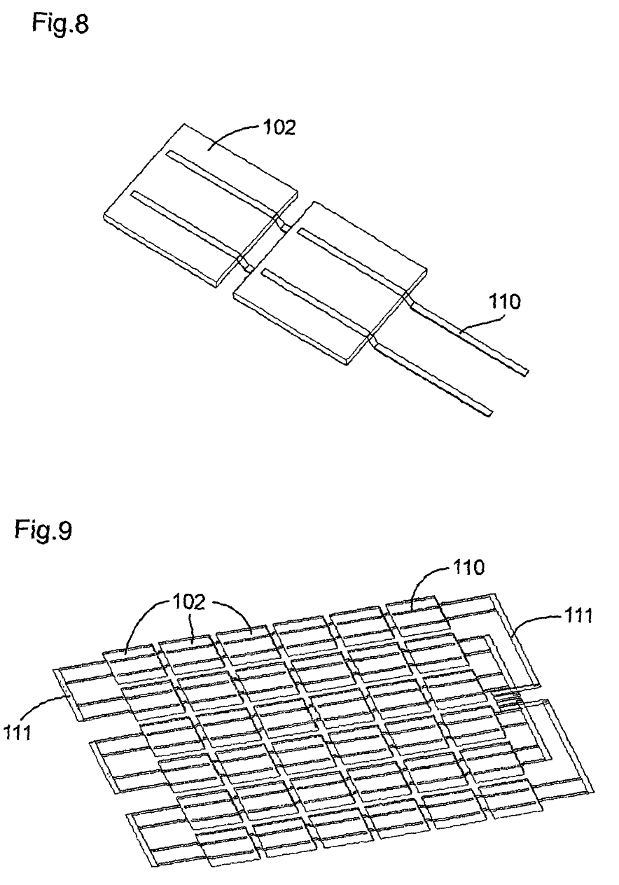

FIG. 8 illustrates two cells with front and back contacts connected in series.

FIG. 9 shows schematically a module composed of cells as illustrated in FIG. 8 obtained by a conventional method, on which the peripheral connections have been effected.

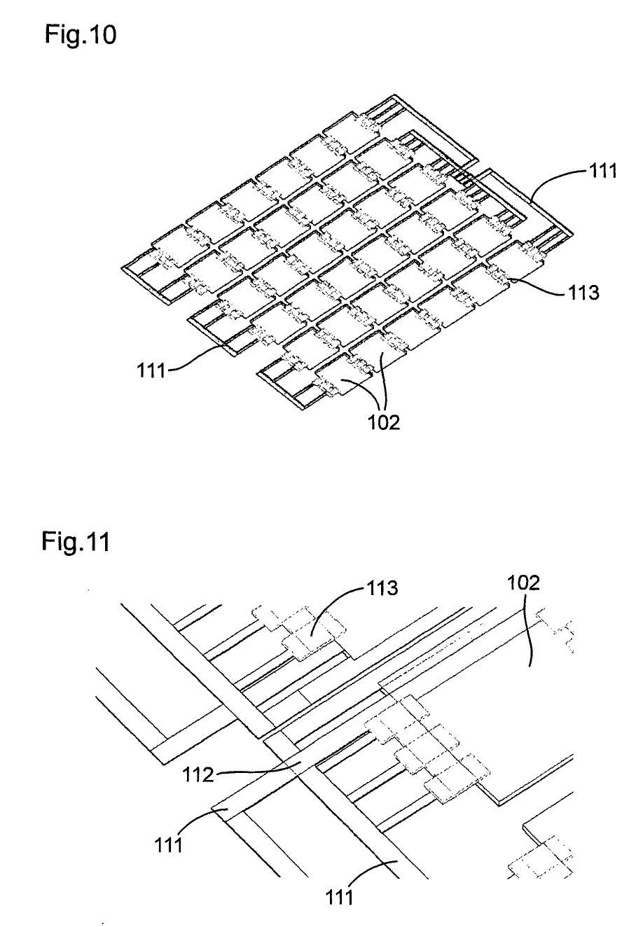

FIG. 10 shows a module composed of back-contact cells obtained by a conventional method and also illustrating the peripheral connections.

FIG. 11 is a partial enlargement of FIG. 10.

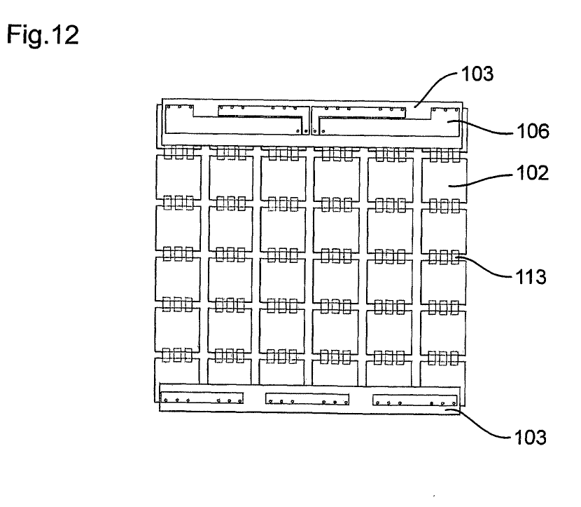

FIG. 12 illustrates a module composed of back-contact cells manufactured by a conventional method for connecting the cells together, on which the peripheral connections are effected using a flexible film provided with a printed circuit.

FIG. 13 shows a top and bottom view respectively of terminal cells with front and back contacts.

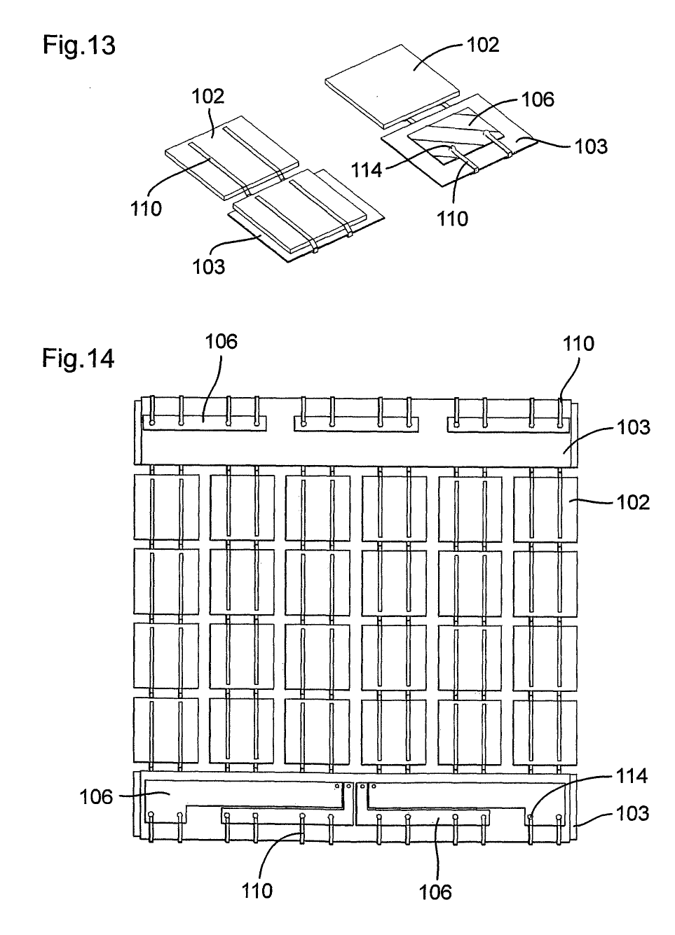

FIG. 14 shows a module of cells with front and back contacts on which the peripheral connections are effected using two strips of flexible film provided with a printed circuit.

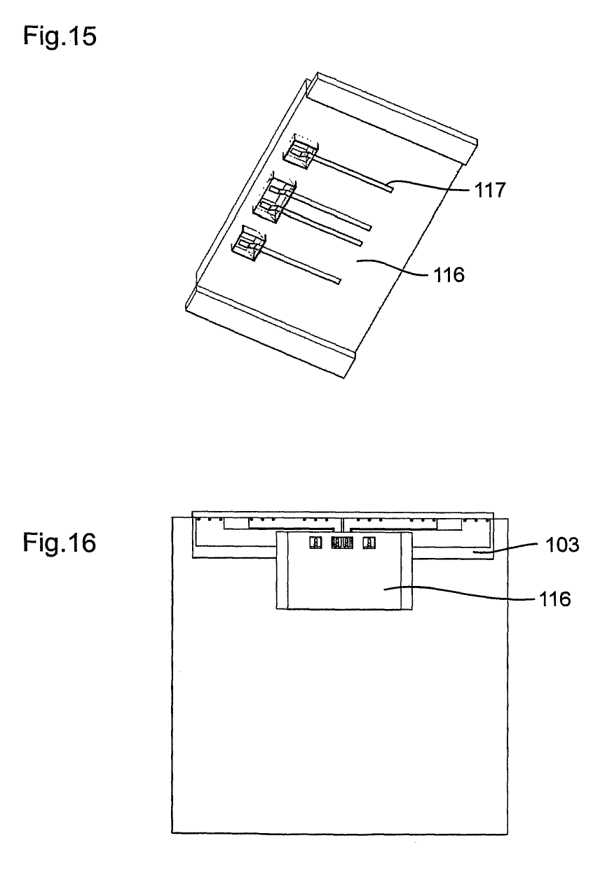

FIG. 15 is a view of a junction box designed to be fitted on the back of the solar panels.

FIG. 16 illustrates schematically the back of a solar panel to which a junction box is connected.

At present the photovoltaic industry benefits from a special dispensation from the European standards on RoHs lead-free soldering because current methods cannot provide good adherence of the cell, nor a good long-lasting hold. The manufacturing method of the invention overcomes this problem and makes the method particularly attractive when considering module recycling costs. It is no longer necessary to carry out costly complicated recycling to remove the lead from manufactured solar panels if one uses the method of the invention. This method also enables a complete step to be eliminated during the manufacture of photovoltaic modules. All peripheral connections can now be made in a single step to the back of the film.

In known methods, the ribbons providing the peripheral cell connections must be insulated to prevent electric arcs and also to permit connection to the junction box located on the back of the modules. The steps required for conventional peripheral connection and insulation are eliminated, which saves time and increases reliability significantly. It will also be noted that the stage in the manufacturing process relative to peripheral connections using film can be applied equally to back-contact cells and cells with back and front contacts.

One soldering method used in other fields is that known as wave soldering, the principle of which is to solder by means of a wave passing across a plated hole. This method is quick, lends itself well to automation and gives good results. This technique is used in particular in the manufacture of integrated circuits, but it has not yet been possible to use it in the manufacture of solar panels mainly because the temperatures of the solder baths are too high and damage the photovoltaic cells during soldering. This is especially so when one wishes to carry out lead-free soldering which requires an increase in bath temperature of 30 to 40 degrees compared with conventional tin/lead soldering. When cells are exposed to too high a temperature, micro cracks and deformation appear in the cells which reduces their life considerably. In lead-free soldering methods, wetting is also not as good as in conventional tin/lead soldering.

To solve these problems and enable a lead-free wave soldering method to be used to interconnect the back contacts of photovoltaic cells, it has first been necessary to develop a multi-layered flexible film presenting the characteristics required to withstand the high temperatures of lead-free solder baths and also to provide the electrical and mechanical properties and durability essential in the manufacture of solar panel modules, while being capable of receiving the copper conductor traces.

According to the embodiment illustrated in FIG. 4, the macro printed circuit 105 effected on the backing film 103, on which photovoltaic cells 102 are fixed by soldering, provides the electrical connection between these cells 102.

The photovoltaic cells 102 used in the method of this invention are cells whose connection points are situated only on their rear sides.

Preferably, the flexible backing or film 103 is made by joining two layers of materials presenting different properties. The top layer of this film 103 is preferably of vinyl polyfluoride sold for example under the brand name Tedlar®. This material presents the following characteristics:
excellent mechanical strength,
weathering resistance,
resistance to ultraviolet radiation and humidity.

Tedlar® also presents excellent long-term stability, and its use is recognised by the photovoltaic industry.

The bottom layer preferably will be made of an insulating material resistant to high temperatures such as those found in wave soldering operations. A material such as Mylar® for example has properties that make it preferable to other materials when considering an industrial application of the method according to the invention. Mylar® presents the following characteristics:
excellent chemical resistance, resistance to oil, grease and humidity. It is particularly suitable for plating, printing or stamping. This property is a major asset for receiving copper traces by different chemical reactions or vaporisation.
It resists mechanical stresses (tears), which means that it can be used in rapid continuous roll-to-roll processing.
It combines easily with other materials, which allows it to be joined without difficulty, for example by lamination, to Tedlar® or copper film.
It resists high temperatures especially well, which enables it to be used in the high temperature conditions imposed by lead-free soldering methods.
It is also an excellent insulator of electricity.
It is stable, which enables its use in solar modules to be envisaged for a period in excess of 25 years.

Joining Tedlar® to Mylar® combines the advantages of both materials. Tedlar® on the front side exposed to solar radiation provides a film resistant to ultraviolet radiation and weathering and presents excellent mechanical strength. Mylar® on the rear side enables the electrical connections to be effected by a lead-free soldering method.

Due to the properties of these two materials, one obtains a thin flexible film, which prevents micro cracks appearing in the cells.

Numerous tests have been carried out to determine the optimum parameters for making the flexible film 103. As a non-limitative example, a layer of Tedlar® with a thickness of between 15 and 45 microns, preferably 25 microns, joined to a layer of Mylar® between 75 and 125 microns thick, preferably 100 microns, has produced excellent results. The thin flexible film 103 thus obtained can be used in the wave soldering method described further on.

To make the flexible film 103 which comprises the macro printed circuit 105 on its underside as illustrated in FIG. 4 for example, a layer of Tedlar® and a layer of Mylar® are put together as explained above, these two layers are then sandwiched between two layers of copper around 35 microns thick after which the four layers are attached together by lamination for example. A conventional method is then used to produce the printed circuit 105 on the layer of Mylar® by removing the areas of copper that do not form part of the circuit to be produced. The upper layer of copper only serves in practise to enable the connection holes 104 to be plated, and to produce pads where the solder tack will be to concentrate the heat and prevent the tin from the solder bath running under the cell. Preferably, the tack pads will comprise deformation inhibitors that help to concentrate the heat in the solder tack and prevent heat dissipating to the cells and copper strip. The residual upper layer of copper is then removed to reveal the Tedlar® on the front side of the film.

Holes can be made in the layers of film 103 not receiving copper traces to improve encapsulant circulation during the laminating stage.

The macro printed circuit 105, for its part, is made by eliminating part of the copper coating the Mylar® to form connecting traces to interconnect the cells, and peripheral connections to connect the junction box 116 generally situated on the rear side of the solar modules (FIG. 19).

It is evident that other materials with the essential properties mentioned above could be used to form the flexible film 103.

At present, the Tedlar®/Mylar® pairing presents the most favourable quality-price ratio for industrial application.

The photovoltaic cells 102 are positioned on the front side of the backing film 103 opposite the side comprising the macro printed circuit 105. This front side comprises several plated holes 104 as illustrated by FIG. 2. These holes 104 are made in such a manner that they coincide with the connection points 107 (FIG. 5) of said cells 102.

The connection points 107 of the photovoltaic cells 102 are at present preferably aligned equidistant from each other in rows of three situated on either side of said cell 102 (FIG. 5), but in the present method they can be of any number and located anywhere.

Holes 104 are provided in the backing film 103 to coincide with these points 107 when the cells 102 are positioned on said film 103. These holes 104 are plated, favouring capillary soldering of the filler metal 126.

The back of the film 103 as illustrated in FIG. 4 comprises said printed circuit 105 consisting of copper traces 106 made by a circuit printing process, the traces 106 being optimised according to each cell type and the number thereof so as to connect the cells 102 in series. These traces 106, which are generally of tinned copper, are dimensioned to withstand normal operating voltages and to prevent insulation breakdown in the photovoltaic cells 102. All of the holes 104 are covered by or connected to the said traces 106 so that they can connect electrically all of the cells 102 provided on the front side of the backing film 103.

To prevent splashes of material during the wave soldering operation, those parts of the traces 106 not coinciding with a hole 104 preferably will be covered with a protective film.

The printed circuit is generally designed to receive an array of between two and n×2 cells and provide the interconnection thereof.

The electrical interconnection of these cells 102 allows modules of different sizes to be produced. These are generally composed of said cells encapsulated between two glass sheets or between a glass sheet and a plastic film. As a general rule, modules used as a solar tile are made of 6 photovoltaic cells (FIGS. 1, 3 and 4) while a current solar module or panel is made up for example of 72 cells.

For this type of module, a single backing film 103 can be made on the same principle. However, with existing soldering machines, one must work in 4 quarters. The 4 backing films 103 are arranged side by side as illustrated in FIG. 7, said films 103 being attached together by connecting tags 115 soldered to the different films 103.

Depending on the type of module manufactured, it is also possible to work in other configurations according to the number of cells fitted. In all cases the film 103 can be pre-cut or delivered in a single roll.

The method for manufacturing solar modules of this invention will now be described in detail. It comprises the following stages.
unrolling of the flexible film 103 continuously or by a conveying carriage,
stoppage of the flexible film 103 at a solder mask, said mask being fitted against the side of the film comprising the macro printed circuit 105 in order to cover all of the backing film 103 except the holes 104,
positioning of the photovoltaic cells 102 on the side of said film 103 opposite the side with said printed circuit 105, the connection points 107 of said cells 102 being placed at the appropriate locations exactly opposite the plated holes 104 of the film 103. Preferably, a method will be used to position the cells that not only positions the cells accurately on the top face of the film 103 but also keeps them flush against said film 103. As the cells have a tendency to deform under heat, it is important that they are flush against the backing when going through the wave. The system for holding the cells against the backing preferably will be thermally insulated so that heat is not absorbed rapidly during soldering. Known methods of the Bernoulli type for example are perfectly suited to this operation,
selective min-wave soldering of the photovoltaic cells 102 to the connection points 107 on the backing film 103.

The solder mask is a replica of the front side of the film 103 with holes in identical positions, as illustrated in the FIG. 2. To avoid damaging the film 103 during selective mini-wave soldering, due to the high temperatures of the bath, the solder mask will preferably be made of an aluminium table with two walls between which a flow of air is circulated to cool the film 103.

The selective mini-wave soldering machine effects the connection between the connection points 107 of the photovoltaic cells 102 and the traces 106 of the macro printed circuit 105. The selective mini waves solder all holes 104 by capillary action. The interconnection of all photovoltaic cells 102 and the electrical connections of all cells 102 with the exterior are therefore performed in a single operation with this method.

To increase the wetability of the plated holes 104, and thus improve soldering, a prior fluxing stage can be provided during which the film is exposed to an appropriate flux of the CORBAR 936B5 type for example.

During the fluxing stage, only the film 103 may be exposed. In general, the plating of the cell contact points presents better wetability than that of the film 103 where the hole plating is generally obtained by galvanisation. The flux applied to the film increases the wetability of the plated holes 104 and thus improves the quality of the solder joints obtained. This flux evaporates during soldering and does not react with the surrounding materials.

Tests have been carried out on a conventional RoHS wave soldering machine to perform a lead-free solder joint. The use of this machine has produced very good results which can be improved even further by the use of a selective mini-wave soldering machine. Tests have shown that the most important criteria for optimum solder joints are not temperature and flux, but rather the provision of maximum wave height. Wave height increases the strength of the solder joint, the capillary rise effect of the filler metal in the plated hole being less significant than when soldering a cross member. By adjusting the selective mini-wave parameters, it is also possible to envisage the holes 104 being unplated.

The selective mini-wave soldering machine for a photovoltaic application has been developed in parallel with the development of the method.

As a non-limitative example, a led-free tin of the type SAC 305 (Sn 96.5%, Ag 3%, Cu 0.5%) can be used to wave solder the photovoltaic cells 102 on a flexible film 103 consisting of a layer of Tedlar® joined to a layer of Mylar®.

The selective wave soldering operation can also be carried out in a nitrogen environment. This further improves the quality of the solderjoints, especially by allowing thinner solders to be made. So obtaining solder joints that are as flat as possible improves the quality of the solar module lamination operations that generally follow the cell soldering stages.

FIG. 6 shows a detailed view of a plated hole 104 in which tinned copper 125 has been deposited on the inner circumference of the hole 127 to plate it. A solder joint is effected in the hole 104 to solder a connection point 107 of a photovoltaic cell 102 to a trace 106 of the macro circuit 105 incorporated in the film 103.

In the soldering process, the filler metal binds the metal of said holes 104 to the metal of the connection points 107 of the cells 102.

The plated holes 104 are of the order of 2 to 4 millimetres in diameter, preferably 3 millimetres which produces good quality solders with an accuracy in the order of a tenth of a millimetre.

This method allows the process of connecting the cells 102 together to be automated. The cells, once interconnected, are then encapsulated between two films 112, preferably of EVA or a similar material, then between two layers of glass 113 or between a layer of glass and a layer of Tedlar®, as in conventional photovoltaic modules.

Apart from the simplicity of realisation and the quality of the connections between the photovoltaic cells 102, this soldering method offers other advantages. Contrary to existing methods known as “tabbing” and “stringing” cells together to form a panel of electrically connected cells, in this invention the cells can be of any thickness, thanks to the film that supports and connects them, without the soldered joints coming loose or the cells breaking.

The selective mini-wave soldering method uses a natural physical phenomenon of capillary rise of the soldering element and it is the best means of soldering a photovoltaic cell without exerting mechanical stress on it. Conduction and laser soldering methods concentrate heat on the ribbons or ossicles causing micro cracks to appear in the cells.

By using a lead-free wave or selective mini-wave soldering method according to the invention, high performances and superior durability of the soldered joints and modules can be obtained. Lead soldering as currently practised in the industry produces a displacement of the solder of a few microns in extreme temperature conditions over time, which is not the case in the method of the invention.

Moreover, due to the automation of several stages in comparison with conventional methods, the production costs of such modules can be reduced significantly.

Although the method has been described in relation to existing back-contact cells, it can be applied mutatis mutandis to any photovoltaic cell with multiple connection points situated at the back of the cells, regardless of their location or distribution.

It will be noted that the flexible film 103 described in the method above can also be used to effect only the peripheral connections of solar modules on which the interconnection between cells has been effected by a production method for a module made up of front and back contact cells as illustrated in FIG. 9, or for a module comprising back-contact cells only as shown in FIG. 10.

In the standard configuration of a photovoltaic module, several cells are connected in series by a system that differs from one manufacturer to another.

The objective is always to get a higher voltage and therefore a more powerful module. This connection is generally obtained for cells 102 with front and back contacts using ribbons 110 soldered to the upper and lower surface of the solar cells 102 as illustrated in FIG. 8. When several strips of cells coupled together in series have been placed on the module, these strips must be connected together: this is what is generally called peripheral connection. It is generally effected using ribbons 111 of tinned copper or other metals suited to the type of soldering used. This stage is still often performed manually.

FIG. 9 illustrates schematically an example of the general interconnection of cells and the peripheral connections of a module composed of 36 conventional cells with front and back contacts.

The problems are identical in the case of modules comprised of cells with back contacts only manufactured using different assembly methods from the one described above. As an example, FIG. 10 illustrates a solar module comprising photovoltaic cells 102 with back contacts only. The interconnection of the cells is effected by means of ossicles 113 that connect two adjacent cells electrically in series.

To effect the peripheral connections of this type of module, ribbons 111 are soldered to the cells 102. These ribbons are then connected to a junction box 116 (FIGS. 15 and 16) on the back of the modules. This junction box 116 comprises antiparallel diodes to allow the current to pass when part of the module is in shade.

To effect the peripheral connections of the module to the junction box, it is not only necessary to insulate the ribbons 111 from each other when they overlap, as for example at point 112 in FIG. 11, but also to insulate the ribbons 111 from the back of the cells 102. This insulation is generally effected by adding an additional layer of Tedlar® over each area affected and requires either complex automation or skilled personnel, thereby increasing the costs and/or time required to manufacture the modules.

The use of a strip of flexible film 103 with, on one side, a printed circuit 105 at both ends of the module, allows the peripheral connections to be effected in a single step instead of three steps as required previously (soldering of the ribbons/insulation between the ribbons/insulation of the ribbons from the back of the cells).

The use of a flexible film 103 considerably improves the automation of the production method and renders the resulting product much more reliable. In particular the risk of faulty insulation that could cause a short circuit and fire is eliminated.

The film 103 permits customized peripheral connections to be effected both for modules with back-contact cells (FIG. 12) and for modules made up of cells with front and back contacts (FIG. 10).

FIG. 12 illustrates schematically a module containing back-contact cells 102 that are connected together in series by means of a conventional method using ossicles 113. The peripheral connections of the module are effected through the copper traces 106 of a strip of film 103, as described previously, fitted to each end of the module.

FIG. 13 illustrates, on the left, the front side of two cells 102 with front and back contacts situated on the ends of the module illustrated in FIG. 14. The part on the right of FIG. 14 illustrates the rear side of these same cells connected in series using ribbons 110.

Instead of making holes in the film 103, which would necessitate passing the end of the ribbons 110 inside these holes, the ribbons 110 are simply folded at the last cell, as in a conventional tabbing/stringing step. The ribbons 110 are then soldered directly on to the copper traces 106 of the printed circuit situated on the back of the film 103.

This method does not require any additional equipment; to carry out this operation it is sufficient to change the coordinates of the solder tacks in order to make the connections to the points of contact 114 on existing production lines.

FIG. 14 illustrates a rear view of a solar module composed of cells 102 with front and back contacts connected together in series by ribbons 110. All peripheral connections are made by two strips of flexible film 103 at each end of the module.

This solution presents numerous advantages including but not limited to the following:
integrity of the peripheral connections, all insulation is performed by the printed circuit 105.
automation: the same soldering tools as are used at present on existing production lines can be used without modification.
easier fitting of the junction box.
the peripheral connections are effected in a single step, the insulation steps are no longer necessary.
more output per square meter.

In some modules currently marketed, several ribbons must be laid on top of each other to comply with the electrical architecture of the module. This stacking of ribbons increases the total surface area of the module. Thanks to the film according to the invention, the copper traces 106 replacing the ribbons 111 are placed under the cells 102 thus reducing the total surface area of the module.

The prevailing standards require a certain distance, currently 16 mm, to be left free between the last electrical element making the peripheral connections and the edge of the module, to prevent current leakage.

In conventional methods, the solder tacks must be effected several millimetres from the edge of the cell. By using the film 103, the solder tacks are situated under the cells 102 therefore the zone that must remain free of electrical components is no longer calculated in relation to the ribbons but in relation to the edge of the cell. This solution results in a significant reduction in the quantity of material (glass, Tedlar®, encapsulant, aluminium frame . . . ) required to produce each layer making up the module.

connections relates to the design and incorporation of the junction box fitted to the back of the modules. This junction box is normally flitted after lamination of the module.

In conventional methods, it is necessary, prior to lamination, to pass the ribbons 111 through the encapsulant and Tedlar® then to fix them temporarily with an adhesive on the back of the module to permit lamination. After lamination the ribbons must be removed from the module, then folded to place them in contact with the terminals of the junction box in order to solder them. This stage cannot be automated easily and many manufacturers have to perform this operation manually.

The use of the film according to the invention enables this production phase to be simplified. In effect, the copper traces 106 of the film 103 can follow a path that takes them directly to the junction box 116 as is evident from FIG. 16.

Prior to lamination of the module, a cut is made in the “encapsulant/Tedlar®” layers, and after lamination the junction box is placed at the terminations of the exposed copper traces then the traces 117 of the junction box 116 are soldered to the contact points situated on the back of the module.

It will also be noted that, thanks to this method of effecting the external connections of the modules, it is possible to simplify and reduce the cost of manufacture of the junction boxes 116. The boxes used at present must be open when they are fixed to the back of the module to allow the ribbons to be connected to the connector tabs in the box. Once the box has been soldered, the tabs must be insulated for example by filling them with silicon. Thanks to the method described above, the junction boxes can be made in the factory, all electronic components being placed in a thermally and electrically insulated sealed enclosure. Only the end of the traces 117 of the box emerges from the sealed casing so that the junction box can be fitted more easily and also with greater integrity because the active part of the junction box containing the electronic components has not been open while being fitted.

What is claimed is:

1. A method enabling the electric coupling of photovoltaic cells together and the peripheral connection of the cells to a junction box, said method comprising the following steps:
conveyance of a flexible film continuously or by means of a conveying carriage, said film being obtained by joining a sheet of material presenting properties of resistance to ultra-violet radiation and a sheet of an electrically insulating material resistant to high temperatures, said film comprising on its upper side a plurality of through-holes made in such a manner that they coincide with the connection points situated on the rear side of photovoltaic cells, and on its underside a macro printed circuit permitting the connections between the cells to be effected,
stoppage of the flexible film at a solder mask, said mask being fitted against the side of the film comprising the macro printed circuit so that it covers all of the backing film except the holes,
positioning of the photovoltaic cells on the side of said film opposite the side comprising the said printed circuit, the connection points of said cells being placed at the appropriate locations exactly opposite the plated holes of the film,
wave soldering of the photovoltaic cells to the connection points on the backing film.

2. Method according to claim 1, wherein the soldering operation is effected by a selective mini-wave soldering operation and in that the holes passing through the film are plated.

3. Method according to one of the foregoing claims, wherein the photovoltaic cells are held on the backing film during the selective mini-wave soldering operation.

4. Method according to any one of claims 1 or 2, wherein the selective mini-wave soldering operation is effected in a lead-free tin bath.

5. Method according to any one of claims 1 or 2, wherein the film is obtained by joining a layer of Tedlar® of between 15 and 45 microns thick, preferably 25 microns, to a layer of Mylar® of between 75 and 125 microns thick, preferably 100 microns.

6. Method according to claim 1, in further comprising a fluxing stage of the plated holes in the backing film prior to the wave soldering operation.

7. Method according to claim 1, wherein the solder mask consists of a table with two walls between which a flow of air is circulated.

8. Method according to claim 6, wherein the soldering operation is effected in a nitrogen environment.

9. A thin flexible film comprising a layer of material resistant to ultra-violet radiation and a layer of an electrically insulating material resistant to high temperatures, said film comprising a macro printed circuit on one of its sides and a plurality of through-holes made such that they coincide with the connection points situated on the rear side of photovoltaic cells on which electrical connection is effected, through a macro printed circuit, using a lead-free wave soldering method.

10. Use of a flexible film having a layer of material resistant to ultra-violet radiation and a layer of electrically insulating material resistant to high temperatures, said film comprising a macro printed circuit on one of its sides, to provide the peripheral electrical connections of a module of photovoltaic cells and the electrical connections to a junction box mounted on the rear side of a solar module.

11. Method for manufacturing a photovoltaic module comprising any number of photovoltaic cells the electrical connections of which are effected according to the method claimed in claim 1, comprising a lamination stage of the assembly consisting of the flexible film and the photovoltaic cell, then an encapsulating operation of this assembly between two EVA films with suitable chemical and physical properties and finally the encapsulation of the resulting module between two layers of glass or a layer of glass and a layer of a material resistant to ultra-violet radiation.

12. A solar panel comprising any number of photovoltaic cells the electrical connection in series of which is obtained by the use of a connection method according to claim 1.

13. A solar panel comprising any number of photovoltaic cells electrically connected together, comprising peripheral connections of said solar panel that are effected by a macro printed circuit provided on one side of a film consisting of a layer of material resistant to ultra-violet radiation and a layer of electrically insulating material resistant to high temperatures.

14. Method permitting the peripheral connection of a module comprising photovoltaic cells connected in series, to be effected to a junction box, comprising at two ends of said module is assembled a strip of film obtained by joining a sheet of material presenting properties of resistance to ultra-violet radiation and a sheet of an electrically insulating material resistant to high temperatures, said film comprising on its underside a macro printed circuit permitting the connections between the rows of cells and to the pins of a junction box to be effected by soldering.
